(19) United States
(12) Patent Application Publication
(10) Pub. No.: US 2026/0002980 A1
(43) Pub. Date: Jan. 1, 2026

(54) SYSTEMS AND METHODS FOR INITIALIZING AND CALIBRATING ASYMMETRIC DIE-TO-DIE INTERFACES

(71) Applicant: Microsoft Technology Licensing, LLC, Redmond, WA (US)

(72) Inventors: Simon Shichi LI, Cupertino, CA (US); Michael Raymond TROMBLEY, Cary, NC (US); Charles Walter BOECKER, Ames, IA (US)

(21) Appl. No.: 18/754,964

(22) Filed: Jun. 26, 2024

(51) Int. Cl. G01R 31/28; G01R 35/00

(52) U.S. Cl. CPC G01R 31/2853; G01R 35/005

(57) ABSTRACT

Systems and methods for initializing and calibrating asymmetric die-to-die (D2D) interfaces are described. As an example, during the calibration of a parameter, a calibration finite-state machine (CAL FSM) can perform certain measurements and adjustments. Once a stage of calibration is finished, the CAL FSM can communicate this information to a cluster FSM. The cluster FSM can then communicate to the node FSM the completion status. Once all the clusters have communicated to the node FSM that they have finished the current stage of calibration, the node FSM advances to the next stage of calibration and communicates to the pertinent cluster FSMs to advance, which in turn communicate to the CAL FSMs within the cluster to advance to the next stage of calibration. The clusters that are communicating in one direction are now able to receive the calibration stage information via other clusters that are communicating in the other direction.

### BACKGROUND

Die-to-die (D2D) links are an integral aspect of advanced packaging technologies, including packaging technologies for integrating separate dies into multi-die systems. Example topologies of integrated dies include horizontally integrated dies (e.g., chiplets in a plane) and vertically integrated dies (e.g., 2.5D, 3D, and silicon bridge topologies). A large monolithic chip, e.g., a system on chip (SoC), can be split into multiple smaller dies, which are referred to as chiplets. Example protocols for interconnecting the dies, including chiplets, in such topologies include Universal Chiplet Interconnect Express (UCle), Bunch Of Wires (BOW), and OCP's OpenHBI Specification (OHBI).

Die-to-Die (D2D) links are used to integrate portions (located on separate chiplets/dies) of large systems, such as SoCs, into a single system. The bandwidth required from the D2D links across a die edge can be asymmetrical or symmetrical. As an example, a certain application may require more transmit bandwidth than receive bandwidth while another may require the opposite. For example, D2D links from an SoC chiplet to an HBM chiplet may be required to support more bandwidth for read operations relative to the write operations.

D2D links require calibration to ensure proper operation. In many instances, D2D interfaces that have an asymmetric bandwidth cannot be calibrated using traditional approaches. This is because a D2D interface with an asymmetric bandwidth may have transmit endpoints that cannot be paired with a receive endpoint on the same die. This, in turn, complicates the handshake process between the D2D links on the two dies that are being calibrated and initialized. Accordingly, there is a need for systems and methods for initializing and calibrating asymmetric die-to-die interfaces.

### SUMMARY

In one example, the present disclosure relates to a method for calibrating an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The method includes using a respective calibration finite-state machine (CAL FSM) for each of the first set of link macros and the second set of link macros, initiating a first stage of calibration for a calibration parameter associated with the asymmetric D2D interface.

The method may further include upon completion of the first stage of the calibration at a macro level, each CAL FSM communicating calibration-related information for the first stage of calibration to a respective cluster-level FSM. The method may further include each cluster-level FSM communicating the calibration-related information for the first stage of calibration to a respective node-level FSM.

The method may further include the respective node-level FSM communicating back to each cluster-level FSM any calibration-related information for the first stage of calibration. The method may further include each cluster-level FSM communicating back the calibration-related information for the first stage of calibration to respective CAL FSMs, allowing for completion of the first stage of calibration for the calibration parameter associated with the asymmetric D2D interface.

In another example, the present disclosure relates to a calibration system for an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The calibration system includes a respective calibration finite-state machine (CAL FSM) for each of the first set of link macros and the second set of link macros to initiate a first stage of calibration for a calibration parameter associated with the asymmetric D2D interface.

Upon completion of the first stage of the calibration at a macro level, each CAL FSM may be configured to communicate calibration-related information for the first stage of calibration to a respective cluster-level FSM. Each cluster-level FSM may be configured to communicate the calibration-related information for the first stage of calibration to a respective node-level FSM.

The respective node-level FSM may be configured to communicate back to each cluster-level FSM any calibration-related information for the first stage of calibration. Each cluster-level FSM may be configured to communicate back the calibration-related information for the first stage of calibration to respective CAL FSMs, allowing for completion of the first stage of calibration for the calibration parameter associated with the asymmetric D2D interface.

In yet another example, the present disclosure relates to a calibration system for an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The calibration system includes a respective calibration finite-state machine (CAL FSM) for each of the first set of link macros and the second set of link macros to initiate a first stage of calibration for a calibration parameter associated with the asymmetric D2D interface.

Upon completion of the first stage of the calibration at a macro level, using a data lane associated with the asymmetric D2D interface, each CAL FSM may be configured to communicate calibration-related information for the first stage of calibration to a respective cluster-level FSM. Each cluster-level FSM may be configured to communicate the calibration-related information for the first stage of calibration, using the data lane associated with the asymmetric D2D interface, to a respective node-level FSM.

The respective node-level FSM may be configured to communicate back to each cluster-level FSM any calibration-related information for the first stage of calibration using the data lane associated with the asymmetric D2D interface. Each cluster-level FSM may be configured to communicate back the calibration-related information for the first stage of calibration to respective CAL FSMs, using the data lane associated with the asymmetric D2D interface, allowing for completion of the first stage of calibration for the calibration parameter associated with the asymmetric D2D interface.

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter.

### BRIEF DESCRIPTION OF THE DRAWINGS

The present disclosure is illustrated by way of example and is not limited by the accompanying figures, in which like references indicate similar elements. Elements in the figures are illustrated for simplicity and clarity and have not necessarily been drawn to scale.

FIG. 1 shows an example die-to-die (D2D) node for use as part of a multi-die system with initialization and calibration of an asymmetric die-to-die interface;

FIG. 2 shows additional details of a D2D transmit link macro and a D2D receive link macro for use with the D2D node of FIG. 1;

FIG. 3 shows a block diagram of an example multi-die system with initialization and calibration of an asymmetric die-to-die interface;

FIG. 4 shows an example modular D2D transmit link macro for use as part of multi-die systems with initialization and calibration of an asymmetric die-to-die interface;

FIG. 5 shows a block diagram of an example D2D transmit link macro for use with multi-die systems with initialization and calibration of an asymmetric die-to-die interface;

FIG. 6 shows a block diagram of an example D2D receive link macro for use with multi-die systems with initialization and calibration of an asymmetric die-to-die interface;

FIG. 7 shows an example set of D2D transmit link macros for use with multi-die systems with initialization and calibration of an asymmetric die-to-die interface;

FIG. 8 shows an example set of D2D receive link macros for use with the set of D2D transmit link macros of FIG. 7;

FIG. 9 shows an example asymmetric die-to-die interface requiring initializing and calibrating of the D2D links;

FIG. 10 shows a calibration system associated with one of the D2D nodes of FIG. 9;

FIG. 11 shows a calibration system associated with the other one of the D2D nodes of FIG. 9;

FIG. 12 shows a flow chart of a method for calibrating an asymmetric die-to-die (D2D) interface between a first die and second die.

### DETAILED DESCRIPTION

Examples described in this disclosure relate to multi-die systems with modular die-to-die link macros with initializing and calibrating of asymmetric die-to-die interfaces. Die-to-die (D2D) links are an integral aspect of advanced packaging technologies, including packaging technologies for integrating separate dies into multi-die systems. Example topologies of multi-die systems include horizontally integrated dies (e.g., chiplets in a plane) and vertically integrated dies (e.g., 2.5D, 3D, and silicon bridge topologies). A large monolithic chip, e.g., a system on chip (SoC), can be split into multiple smaller dies, which are often referred to as chiplets. As used herein the term “die” includes any block of material (e.g., semiconducting material or other types of materials used in manufacturing of integrated circuits on a shared substrate) having integrated circuits, where the die can be packaged. The term “dies” includes chiplets, which are typically smaller than a die.

Die-to-Die (D2D) links are used to integrate portions (located on separate chiplets/dies) of large systems, such as SoCs, into a single system. The bandwidth required from the D2D links across a die edge can be asymmetrical or symmetrical. As an example, a certain application may require more transmit bandwidth than receive bandwidth while another may require the opposite. For example, depending upon the application context, D2D links from an SoC die to an HBM stack of dies may be required to support more bandwidth for the read operations relative to the write operations, or conversely less bandwidth for the read operations relative to the write operations. Example industry standard protocols for interconnecting the dies include Universal Chiplet Interconnect Express (UCle), Bunch Of Wires (BOW), and OCP's OpenHBI Specification (OHBI). Such standards offer the benefits that are typically associated with industry standardization but they are not flexible in terms of their use in disparate bandwidth scenarios, as noted earlier. The current standards (UCle, BoW, OHBI) for interconnecting dies assume symmetrical interfaces with respect to bandwidth.

D2D interfaces require calibration to ensure proper operation. In many instances, D2D interfaces that have an asymmetric bandwidth cannot be calibrated using traditional approaches. This is because in a D2D interface with an asymmetric bandwidth, there may be transmit endpoints that cannot be paired with a receive endpoint on the same die. This, in turn, complicates the handshake process between the D2D links on the two dies that are being calibrated and initialized. Accordingly, there is a need for systems and methods for initializing and calibrating asymmetric die-to-die interfaces.

To calibrate symmetric D2D interfaces, a back-channel is used during the calibration process to enable communication between finite-state machines (FSMs) on each end of the interface. The use of the back-channel allows the FSMs on each die to effectively stay synchronized. This, in turn ensures that proper stimulus/measurements are occurring at the appropriate time (e.g., in a synchronized fashion). As an example, the FSM associated with a transmit endpoint may start the calibration process by calibrating the transmit clock trees after ensuring the phase-locked loop (PLL) associated with the transmit clock is fully functional. Once the FSM associated with the transmit endpoint has completed this process, then the FSM can notify the FSM associated with the receive endpoint, via the back-channel, that the receive-side FSM can now start the next stage of the calibration process. This way, the process can go from one stage to the next in a synchronized fashion until all of the transmit endpoints and the receive endpoints have completed the calibration process for all of the D2D links associated with the D2D interface.

As noted earlier, D2D interfaces with an asymmetric bandwidth have transmit endpoints that cannot be paired with a receive endpoint on the same die. This, in turn, complicates the handshake process between the D2D links on the two dies that are being calibrated and initialized. Examples described herein relate to a hierarchical organization of finite-state machines, and a related calibration process for an asymmetrical D2D interface. The enablement of the asymmetrical D2D interface allows bandwidth to be appropriately assigned to either the transmit side or the receive side to optimize the bandwidth usage on a per use case basis.

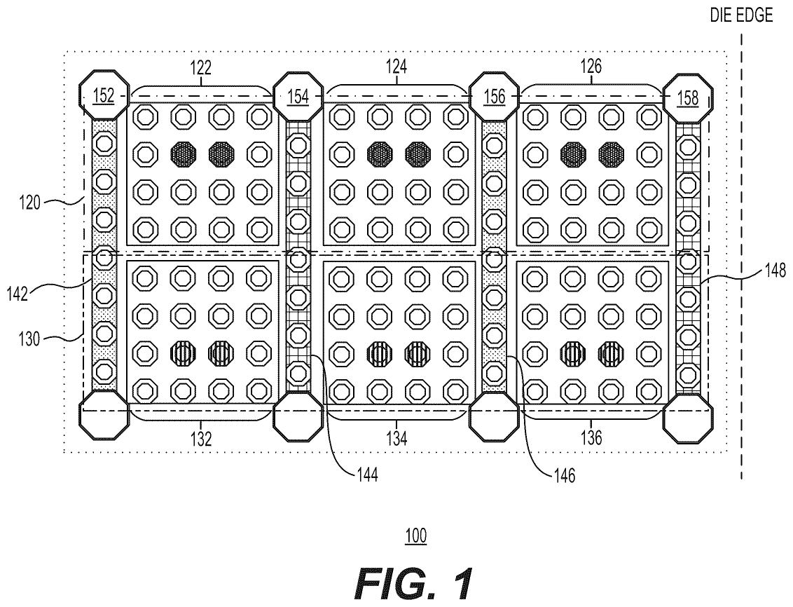

FIG. 1 shows an example die-to-die (D2D) node 100 for use as part of a multi-die system with initialization and calibration of an asymmetric die-to-die interface. Each D2D node can be viewed as a physical aggregation of components, where each of the components further includes sub-components. The vertical dotted line shown in FIG. 1 identifies the die edge for D2D node 100. In this example, each D2D node 100 includes one or more clusters of D2D link macros. Each D2D link macro may only be a transmit link macro or a receive link macro. While one could combine transmit link macros and receive link macros in the form of clusters or another such arrangement, each D2D link macro is limited to being only one of a kind—a transmit link macro or a receive link macro. In this example, D2D node 100 is shown as including two clusters of D2D link macros. Cluster 120 includes three transmit link macros 122, 124, and 126. Cluster 130 includes three receive link macros 132, 134, and 136. In this example, each cluster shares a clock spine, which is used to distribute clock signals to all of the D2D link macros included in a respective cluster.

With continued reference to FIG. 1, D2D node 100 includes power and ground distribution via columns of power and columns of ground. In this example, D2D node 100 includes two columns of power-power column 142 and power column 146. Moreover, in this example, D2D node 100 includes two columns of ground-ground column 144 and ground column 148. The combination of these columns, which are arranged between the link macros, allows for efficient distribution of power within the D2D node 100. In addition, D2D node 100 includes several sacrificial (SAC) pads. Probing can be performed using these SAC pads instead of using the micro-bumps associated with the link macros. As an example, D2D node 100 is shown with several SAC pads along the periphery of the D2D node 100, including SAC pads 152, 154, 156, and 158. Although FIG. 1 shows D2D node 100 as having a certain number of clusters and D2D link macros that are arranged in a certain manner, D2D node 100 may include additional or fewer clusters and/or D2D link macros that are arranged differently.

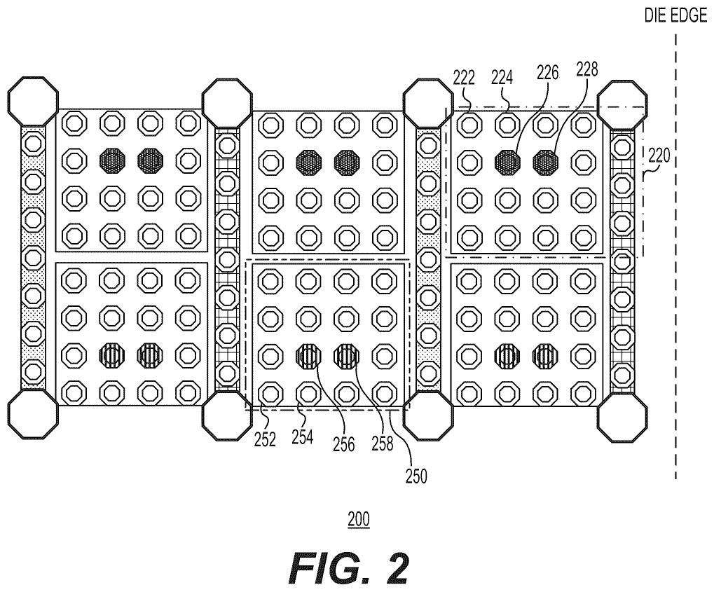

FIG. 2 shows additional details of a D2D transmit link macro 220 and a D2D receive link macro 250 for use with the D2D node 100 of FIG. 1. Each D2D link macro supports the same number of lanes, which can be used to transmit (or receive) data signals or to transmit (or receive) clock signals. D2D transmit link macro 220 includes fourteen data-related bumps and two clock-related bumps. In this example, bumps 222 and 224 correspond to the data-related bumps and bumps 226 and 228 correspond to the clock-related bumps. Similarly, D2D receive link macro 250 includes further data-related bumps and two clock-related bumps. In this example, bumps 252 and 254 correspond to the data-related bumps and bumps 256 and 258 correspond to the clock-related bumps. The bumps themselves may be implemented as micro-bumps or other types of interconnection structures for use with dies. Although FIG. 2 shows D2D transmit link macro 220 and D2D receive link macro 250 as having a certain number of bumps that are arranged in a certain manner, each of these macros may include additional or fewer bumps that are arranged differently.

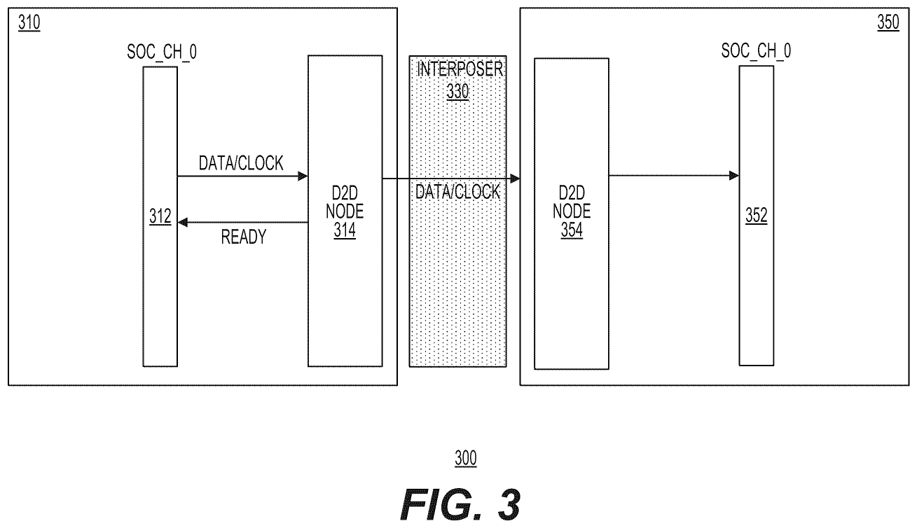

FIG. 3 shows a block diagram of an example multi-die system 300 with initialization and calibration of an asymmetric die-to-die interface. The block diagram for multi-die system 300 shown in FIG. 3 illustrates the logical aspects of the use of the D2D link macros in the context of multi-die systems, such as the multi-die system 300. Multi-die system 300 includes a die 310 coupled with another die 350 using an interposer 330. Die 310 includes D2D node 314 and die 350 includes D2D node 354. The purpose of each of the D2D nodes (having D2D link macros) is to transport the contents of a bus included within one die to another bus included in another die. Die 310 includes a system-on-chip (SoC) channel 312 (SOC_CH_0), which is coupled to D2D node 314, located within die 310. SoC channel 312 can provide data, clock, and valid signals to D2D node 314. D2D node 314 can transmit the data along with a clock signal to D2D node 354 located within die 350 via interposer 330. The SoC channel 832 can receive control signals (e.g., READY) from D2D node 314.

With continued reference to FIG. 3, die 350 includes an SoC channel 352 (also labeled as SOC_CH_0), which can be used to receive data and clock signals from D2D node 354, which is also located within die 350. For ease of explanation, in this example, the busses on the two dies are shown as identical in terms of their bandwidth (e.g., 390 bits). The principal function of the D2D nodes and the D2D links is to transport data from one die to the other die. Any number of SoC channels from die 310 can be transported across the die edge to the interposer 330 and then from the interposer to die 350. As explained earlier, in physical terms, each D2D node can include clusters of D2D link macros that can be transmit link macros or receive link macros. Although FIG. 3 shows multi-die system 300 including a certain number of D2D nodes for enabling configurable die-to-die lane repair, multi-die system 300 may include more or fewer such components, which could be arranged differently from the arrangement shown in FIG. 3.

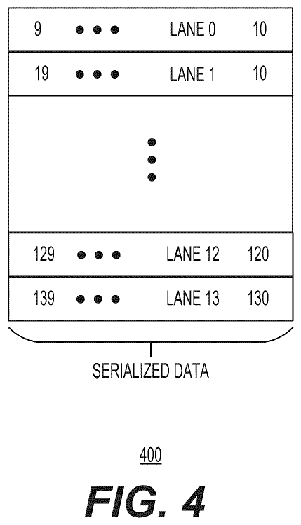

FIG. 4 shows an example modular D2D transmit link macro 400 for use as part of multi-die systems with initialization and calibration of an asymmetric die-to-die interface. As explained earlier, the physical D2D links between the two dies are implemented using a certain number of lanes per D2D link macro and serialization of the data across the D2D links. In this example, the modular D2D transmit link macro 400 is capable of handling 10 bits per lane, which are then sent as serialized data across the physical D2D link, resulting in a serialization of 10:1. Example D2D transmit link macro 400 is shown with fourteen lanes (LANE 0, LANE 1, . . . . LANE 12, and LANE 13). Although FIG. 4 shows the D2D transmit link macro 400 as having a certain number of lanes with a certain number of bits per lane, the D2D transmit link macro 400 could have additional or fewer lanes with a different number of bits per lane.

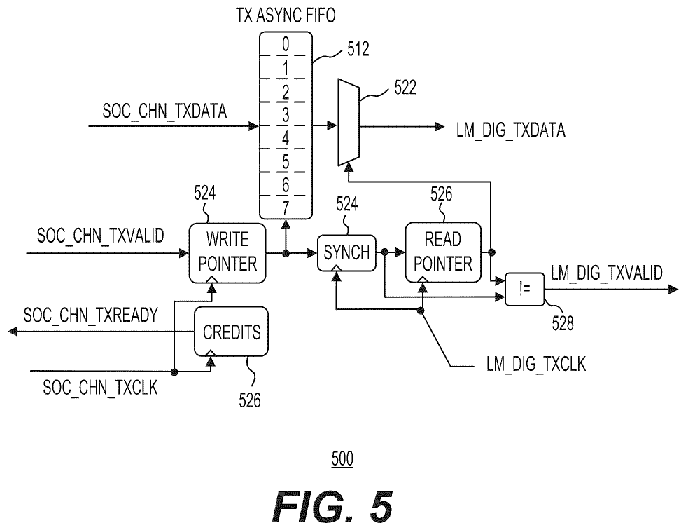

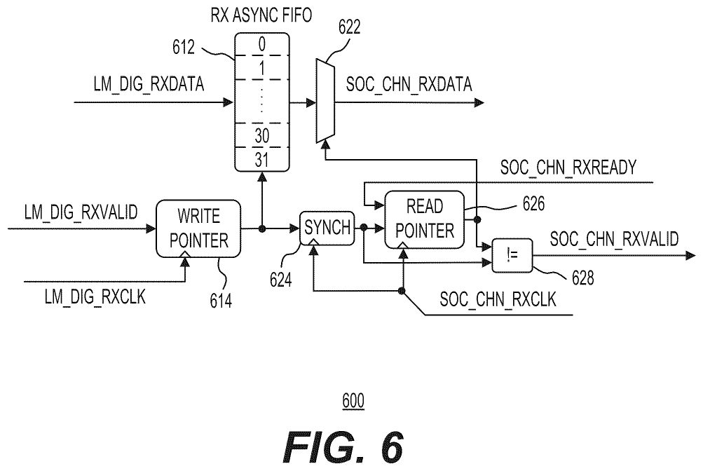

FIG. 5 shows a block diagram of an example D2D transmit link macro 500 for use with multi-die systems with initialization and calibration of an asymmetric die-to-die interface. FIG. 6 shows a block diagram of an example D2D receive link macro 600 for use with multi-die systems with initialization and calibration of an asymmetric die-to-die interface. As an example, D2D transmit link macro 500 could be implemented as the D2D link macro 300 of FIG. 3, which offers a capacity of 10-bits per lane and has 14 data lanes. In this example, D2D transmit link macro 500 is configured to process a system-on-chip (SoC) channel (e.g., a system bus associated with the SoC) with a bandwidth of a certain number of bits (e.g., 140 bits) and provide those for serialization. The serialized data is then transmitted via an interposer (or another packaging structure) to the receive link macros (shown in FIG. 6). The data output by the D2D transmit link macro 500 is serialized prior to the transmission using a serializer block (not shown). Table 1 below provides a brief explanation for the various signals (shown in FIG. 5) associated with the D2D transmit link macro 500.

TABLE 1

| D2D Transmit Link | |
|---|---|
| Marco Signals | Brief Explanation |
| SOC_CHN_TXDATA | Data for transmission from the pertinent SoC |
| | channel to the D2D transmit link macro. |
| SOC_CHN_TXVALID | Control signal for the write pointer from the |
| | pertinent SoC channel indicating valid |
| | transmit data. |
| SOC_CHN_TXCLK | Transmit clock associated with the pertinent |
| | SoC channel. |
| SOC_CHN_TXREADY | Ready signal from the D2D transmit link |
| | macro to the SoC channel. |
| LM_DIG_TXDATA | Data for transmission from the D2D transmit |
| | link macro, which is serialized, and then |
| | transmitted to another die. |
| LM_DIG_TXCLK | Transmit clock associated with the D2D |
| | transmit link macro. |
| LM_DIG_TXVALID | Control signal indicative of whether the |
| | transmit data is valid. |

With continued reference to FIG. 5, in this example, the D2D transmit link macro 500 includes a transmit asynchronous FIFO (TX ASYNC FIFO 512), which is used to receive the data to be transmitted (e.g., SOC_CHN_TXDATA of table 1). The D2D transmit link macro 500 further includes a write pointer 514, a block for managing flow using credits (e.g., CREDITS 516), a synchronization channel block (e.g., SYNCH 524), and a read pointer 526. The write pointer 514 points to the data in the TX ASYNC FIFO 512 and it advances through the FIFO once the write pointer 514 receives a valid signal (e.g., SOC_CHN_TXVALID of table 1). The write pointer 514 is synchronized with the read pointer 526 using the synchronization channel block (e.g., SYNCH 524). As shown in FIG. 5, both the synchronization channel block (e.g., SYNCH 524) and the read pointer 526 are synchronized using a transmit link macro clock signal (e.g., LM_DIG_TXCLK of table 1). This allows the read pointer 526 to follow the write pointer 514 with a certain delay in between. The read pointer 526 outputs a signal that is used to control the output of multiplexer 522, which receives the data to be transmitted from the TX ASYNC FIFO 512. A logic block 528 that implements the !=equality is provided the output of both the read pointer 526 and the synchronization channel block (e.g., SYNCH 524). Logic block 528 processes the two input signals and generates a control signal (e.g., LM_DIG_TXVALID of table 1) indicating whether the data to be transmitted is valid. Although FIG. 5 shows D2D transmit link macro 500 as including certain components arranged in a certain manner, D2D transmit link macro 500 could include additional or fewer components that are arranged differently.

FIG. 6 shows a block diagram of a D2D receive link macro 600 for use with power efficient bidirectional die-to-die communication systems and methods. On the receive side, the serialized data, received via an interposer (or a similar structure), is de-serialized using a de-serializer block (not shown). The de-serialized data is then processed by the D2D receive link macro 600. As an example, if the transmit side sent 140 bits after serialization then the D2D receive link macro 600 processes those bits. Table 2 below provides a brief explanation for the various signals (shown in FIG. 6) associated with the D2D receive link macro 600.

TABLE 2

| D2D Receive Link | |
|---|---|
| Marco Signals | Brief Explanation |
| LM_DIG_RXDATA | Data, which has been de-serialized, |
| | received from another die by the D2D |
| | receive link macro. |
| LM_DIG_RXCLK | Receive clock associated with the D2D |
| | receive link macro. |
| LM_DIG_RXVALID | Control signal indicative of whether |
| | the receive data is valid. |
| SOC_CHN_RXDATA | Data provided by the D2D receive link |
| | to the pertinent SoC channel. |
| SOC_CHN_RXVALID | Control signal for the SoC channel |
| | indicating valid receive data. |
| SOC_CHN_RXCLK | Receive clock associated with the pertinent |
| | SoC channel. |
| SOC_CHN_RXREADY | Ready signal from the pertinent SoC channel |
| | to D2D receive link macro. |

With continued reference to FIG. 6, in this example, the D2D receive link macro 600 includes a receive asynchronous FIFO (RX ASYNC FIFO 612), which is used to receive the de-serialized data (e.g., LM_DIG_TXDATA of table 2). The D2D receive link macro 600 further includes a write pointer 614, a synchronization channel block (e.g., SYNCH 624), and a read pointer 626. The write pointer 614 points to the data in the RX ASYNC FIFO 612 and it is synchronized with the read pointer 626 using the synchronization channel block (e.g., SYNCH 624). As shown in FIG. 6, both the synchronization channel block and the read pointer 626 are synchronized using a SoC channel receive clock signal (e.g., SOC_CHN_RXCLK of table 2). The read pointer 626 outputs a signal that is used to control the output of multiplexer 622, which receives the data from the RX ASYNC FIFO 612 and outputs the received data to the respective SoC channel (e.g., as SOC_CHN_RXDATA of table 2). In terms of reading the data, the read side of the RX ASYNC FIFO 612 waits for all of the pointers to advance to the same value before reading out the location of the RX ASYNC FIFO 612. A logic block 628 that implements the !=equality is provided the output of both the read pointer 626 and the synchronization channel block (e.g., SYNCH 624). Logic block 628 processes the two input signals and generates a control signal (e.g., SOC_CHN_RXVALID of table 2) indicating whether the data for the respective SoC channel is valid. Although FIG. 6 shows D2D receive link macro 600 as including certain components arranged in a certain manner, D2D receive link macro 600 could include additional or fewer components that are arranged differently.

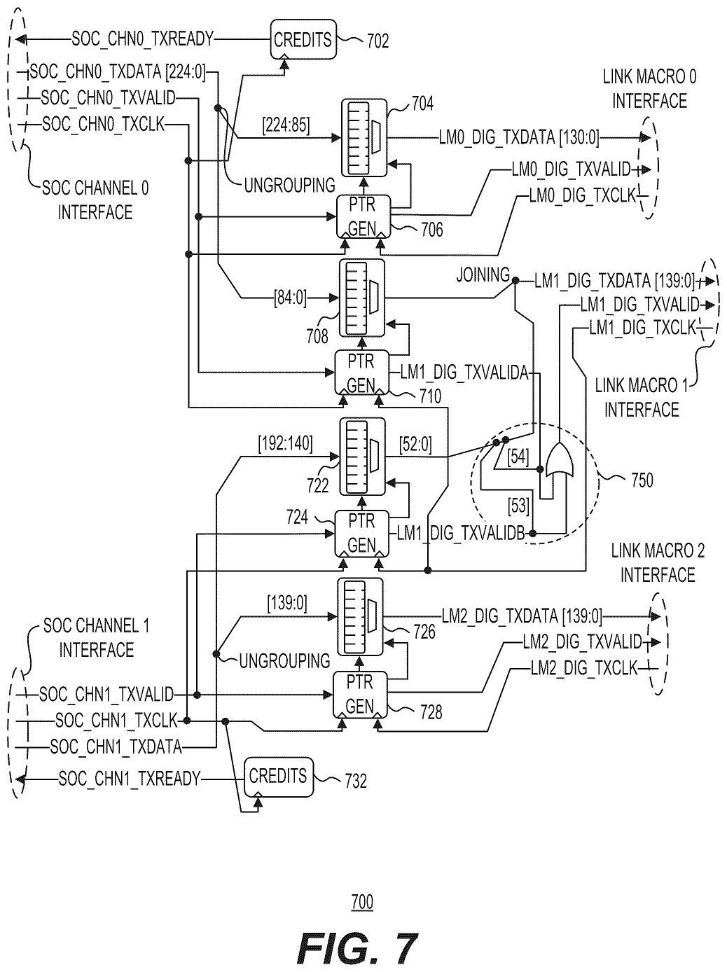

FIG. 7 shows an example set of D2D transmit link macros 700 for use with multi-die systems with initialization and calibration of an asymmetric die-to-die interface. The set of D2D transmit link macros 700 can be used to receive data from one or more SoC channels and transfer the data via D2D links. As described earlier, the D2D transmit link macros can process the data received from the SoC channels, and after serialization, the data can be transmitted via D2D links to another die via an interposer or similar structure. In this example, the set of D2D transmit link macros 700 assumes a lack of perfect alignment in terms of the bandwidth of the pertinent SoC channel and the bandwidth offered by the D2D transmit link macro. As an example, D2D transmit link macros 700 can be implemented with similar components as described earlier with respect to D2D transmit link macro 500 of FIG. 5 with additional logic for ungrouping and joining. In terms of ungrouping, as an example a specific SoC channel having a bandwidth that exceeds the bandwidth of a single D2D transmit link macro can be ungrouped for transport across joined D2D transmit link macros. At the receive side, the ungrouped SoC channel can be grouped using split D2D receive link macros. In this example, to enable grouping and ungrouping, all of the FIFOs at both the transmit side and the receive side are initialized at the same time when the D2D nodes are initialized upon the SoC powering up.

With continued reference to FIG. 7, in this example, the set of D2D transmit link macros 700 is configured to transmit data from two SoC channels: SOC_CH_0 and SOC_CH_1. This example assumes that SOC_CH_0 1 has a bandwidth of 225 bits in terms of the data that requires transmission and that SOC_CH_1 has a bandwidth of 193 bits in terms of the data that requires transmission. In this example, the set of D2D transmit link macros 700 includes three D2D transmit link macros. In this example, each of the set of D2D transmit link macros 700 supports 14 data lanes, where each lane is capable of handling 10 bits (e.g., similar to modular D2D transmit link macro 500 of FIG. 5), resulting in the bandwidth capacity of 140 bits. Notably, in this example, each of the SoC channels has a bandwidth that exceeds the bandwidth capacity of an individual D2D transmit link macro. To allow for transmission of data, the data from the first SoC channel (e.g., SOC_CH_0) is ungrouped into a first group of data and a second group of data. Similarly, the data from the second SoC channel (SOC_CH_1) is ungrouped into a third group of data and a fourth group of data. In this example, a first D2D transmit link macro is configured to transmit the first group of data, a second D2D transmit link macro is configured to transmit both the second group of data and the third group of data, and a third D2D transmit link macro is configured to transmit the fourth group of data.

Still referring to FIG. 7 the data output by each of the set of D2D transmit link macros 700 is serialized prior to the transmission using a serializer block (not shown). Similar signals as described earlier with respect to table 1 in the context of FIG. 5 are associated with the set of D2D transmit link macros 700. In this example, each set of D2D transmit link macro 700 includes some of the same circuitry as described earlier with respect to D2D transmit link macro 500. As an example, the set of D2D transmit link macros 700 include circuitry for flow control, such as credits 702 and credits 732. The set of D2D transmit link macros 700 further includes circuitry associated with FIFOs (e.g., FIFO blocks 704, 708, 722, and 726) and pointer generation (e.g., pointer generation blocks 706, 710, 724, and 728). Each of the FIFOs included in FIFO blocks 704, 708, 722, and 728 waits for all the associated pointers to advance to the same value before reading out the location of the FIFO. The set of transmit link macros 700 further includes control logic 750 for generating signals that permit joining of data for transmission by a shared D2D transmit link macro. A valid signal is inserted into the data path for each SoC bus that is ungrouped. As shown in FIG. 7, bits 53 and 54 carry the valid signal for the two SoC channels that were ungrouped. Using control logic 750, these bits are processed to validate the data and generate the LM1_DIG_TXVALID signal for transmission to the receive side. Although FIG. 7 shows the set of D2D transmit link macros 700 as having a certain number of components that are arranged in a certain manner, the D2D transmit link macros 700 may include additional or fewer components that are arranged differently.

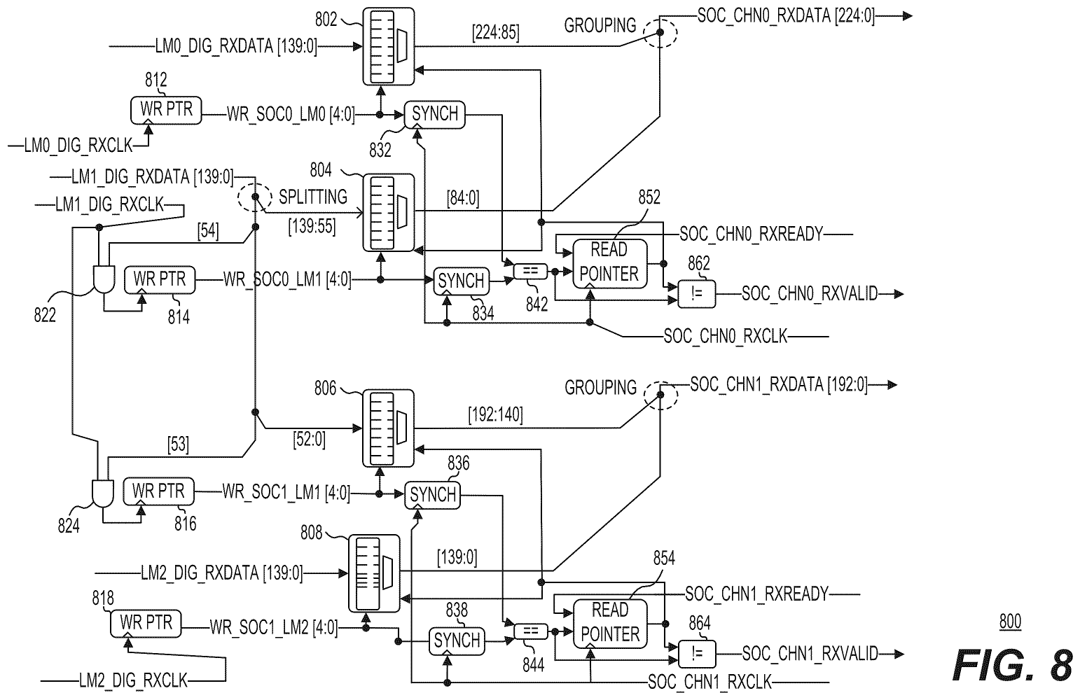

FIG. 8 shows an example set of D2D receive link macros 800 for use with the set of D2D transmit link macros 700 of FIG. 7. The set of D2D receive link macros 800 can be used to receive data via the D2D links. As described earlier, the D2D receive link macros can process the data received from D2D links, and after de-serialization, the data can be transferred to the SoC channels within the SoC (or a similar system). As an example, each of the set of D2D receive link macros 800 can be implemented with similar components as described earlier with respect to D2D receive link macro 600 of FIG. 6 with the additional logic for splitting and grouping. In this example, the set of D2D receive link macros 800 includes three D2D receive link macros. In this example, each of the set of D2D receive link macros 800 supports 14 data lanes, where each lane is capable of handling 10 bits, resulting in a bandwidth capacity of 140 bits. The first group of data corresponding to SoC channel 0 is received via one of the set of D2D receive link macros 800. The second group of data (corresponding to SoC channel 0), which was ungrouped at the transmit side, is received by one of the second set of D2D receive link macros 800. The third group of data (corresponding to SoC channel 1) is received via the one of the second set of D2D receive link macros 800, and the fourth group of data (corresponding to SoC channel 1) is received by one of the third set of D2D receive link macros 800.

With continued reference to FIG. 8, similar signals as described earlier with respect to table 2 in the context of FIG. 6 are associated with the set of D2D receive link macros 800. In this example, each set of D2D receive link macro 800 includes some of the same circuitry as described earlier with respect to D2D receive link macro 600 of FIG. 6. As an example, the set of D2D receive link macros 800 includes circuitry associated with FIFOs (e.g., FIFO blocks 802, 804, 806, and 808) and write pointer generation circuitry (e.g., WR PTR blocks 812, 814, 816, and 818). The set of D2D receive link macros 800 further includes control logic (e.g., AND gates 822 and 824) for generating signals that are used for splitting of the data for processing by a shared D2D receive link macro. The set of D2D receive link macros 800 further includes synchronization channel blocks (e.g., SYNCH 832, SYNCH 834, SYNCH 836, and SYNCH 838), and read pointers (e.g., READ POINTER 852 and READ POINTER 854). As explained earlier with respect to FIG. 6, each respective write pointer points to the data in the respective receive FIFO and it is synchronized with the respective read pointer using the respective synchronization channel block. In terms of reading the data, as described earlier with respect to FIG. 6, the read side waits for all of the pointers to advance to the same value before reading out the location of the receive FIFO. To allow for the grouping of the data received from different SoC channels, logic blocks 842 and 844 that implement the equality operation are used at the input of the respective read pointer. Additional logic blocks 862 and 864 that implement the !=equality are provided the output of both the respective read pointer and the respective logic blocks 842 and 844. Although FIG. 8 shows the set of D2D receive link macros 800 as having a certain number of components that are arranged in a certain manner, the set of D2D receive link macros 800 may include additional or fewer components that are arranged differently.

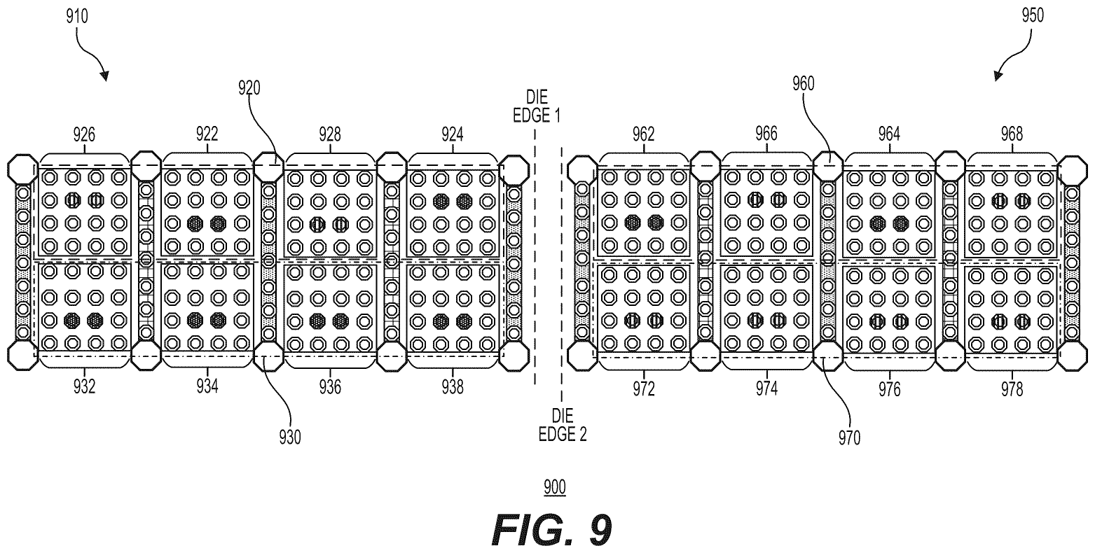

FIG. 9 shows an example die-to-die (D2D) nodes 900 for use as part of a multi-die system with initialization and calibration of an asymmetric die-to-die interface. Each of D2D node 910 and D2D node 950 can be viewed as a physical aggregation of components, where each of the components further includes sub-components. The vertical dotted line on the left (labeled as DIE EDGE 1), shown in FIG. 9, identifies the die edge for D2D node 910. The vertical dotted line on the right (labeled as DIE EDGE 2), shown in FIG. 9, identifies the die edge for D2D node 950. In this example, each D2D node includes one or more clusters of D2D link macros. In this example, each D2D link macro may only be a transmit link macro or a receive link macro. While one could combine transmit link macros and receive link macros in the form of clusters or another such arrangement, each D2D link macro is limited to being only one of a kind—a transmit link macro or a receive link macro. In this example, D2D node 910 is shown as including two clusters 920 and 930 of D2D link macros. Cluster 920 includes two transmit link macros 922 and 924 and two receive link macros 926 and 928. Cluster 930 includes four transmit link macros 932, 934, 936, and 938. In this example, D2D node 950 is shown as including two clusters 960 and 970 of D2D link macros. Cluster 960 includes two transmit link macros 962 and 964 and two receive link macros 966 and 968. Cluster 970 includes four receive link macros 972, 974, 976, and 978. Consequently, in this example, while clusters 920 and 960 are symmetric in terms of bandwidth across the die edges, clusters 930 and 970 are not. This is because cluster 930 includes transmit link macros only and cluster 970 includes receive link macros only. As a result, more data (4× a single BW unit (assuming a pair of a transmit link macro coupled to a receive link macro equates to a single BW unit)) can be transmitted from D2D node 910 to D2D node 950.

With continued reference to FIG. 9, in this example, the D2D links for interconnecting the transmit link macros and receive link macros require calibration to ensure proper operation. In this instance, the D2D interfaces have an asymmetric bandwidth that cannot be calibrated using traditional approaches. This is because in these D2D nodes, transmit endpoints cannot be paired with a receive endpoint on the same die. This, in turn, complicates the handshake process between the D2D links on the two dies that are being calibrated and initialized. Although FIG. 9 shows two D2D nodes 910 and 950 as having a certain number of clusters and D2D link macros that are arranged in a certain manner, D2D nodes 910 and 950 may include additional or fewer clusters and/or D2D link macros that are arranged differently.

To ensure that the D2D nodes (e.g., D2D nodes 910 and 950) with asymmetric bandwidth and no dedicated back-channel stay synchronized during calibration, a hierarchal control is deployed by having finite-state machines (FSMs) at different levels of control, including at the node level, at the cluster level, and at the macro level. A calibration finite-state machine (CAL FSM), measures aspects associated with the circuits being calibrated and changes the circuits, as needed. As an example, during calibration the CAL FSM can measure an impedance for a D2D link associated with a specific link macro, such that it is substantially equal to a reference resistance. Once a particular stage of calibration is finished, the CAL FSM can communicate this information to a cluster FSM (CLUSTER FSM). In one example, the CLUSTER FSM waits for all the link macros within its cluster to complete the current stage of the calibration. The CLUSTER FSM communicates to the node FSM (NODE FSM) the completion status when this occurs. Once all the clusters have communicated to the NODE FSM that they have finished the current stage of calibration, the NODE FSM advances to the next stage of calibration and communicates to the pertinent CLUSTER FSMs to advance. The CLUSTER FSMs, in turn communicate to the CAL FSMs within the cluster to advance to the next stage of calibration. The clusters that are communicating in one direction are now able to receive the calibration stage information via other clusters that are communicating in the other direction. While the die-to-die interface can be asymmetric, there is one constraint that must be met, and it relates to the fact that each die must have at least one link macro of each type within the die. This ensures that all the FSMs on both dies are synchronized properly.

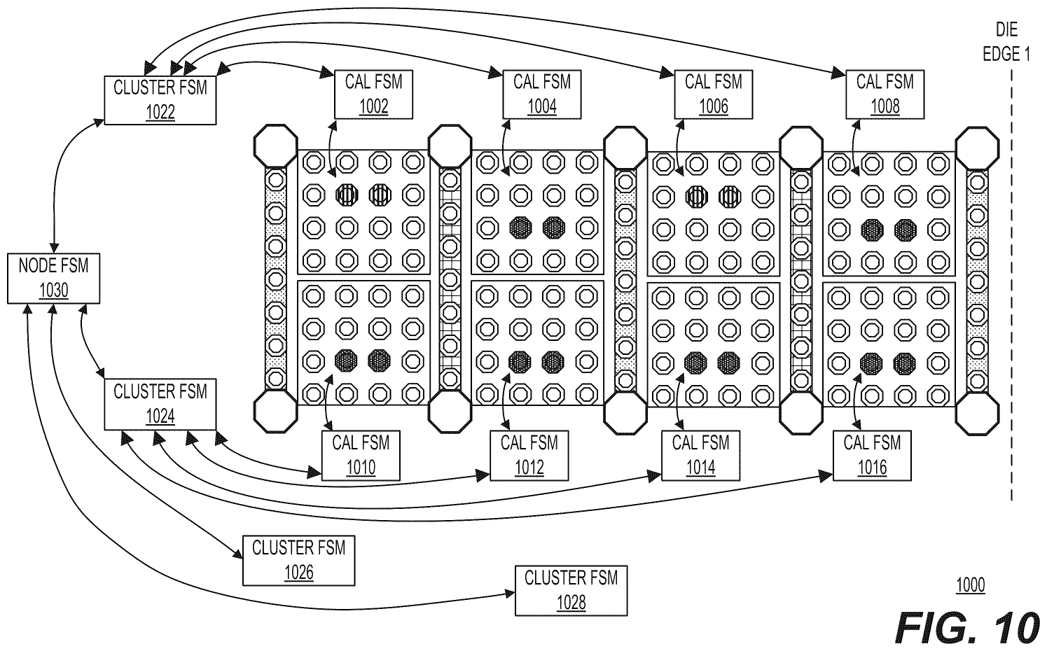

FIG. 10 shows a calibration system 1000 associated with D2D node 910 of FIG. 9. To ensure that the D2D nodes (e.g., D2D nodes 910 and 950 of FIG. 9) with asymmetric bandwidth and no back-channel stay synchronized during initialization and calibration, a hierarchal control is deployed by having finite-state machines (FSMs) at different levels of control, including at the node level, at the cluster level, and at the macro level. A calibration finite-state machine (CAL FSM) measures aspects associated with the circuits being calibrated, and changes the circuits, as needed. Calibration system 1000 includes four CAL FSMs 1002, 1004, 1006, and 1008, which correspond to link macros within the same cluster (e.g., in this case cluster 920 of FIG. 9). In this example, CAL FSM 1002 corresponds to receive link macro 926 of FIG. 9, CAL FSM 1004 corresponds to transmit link macro 922 of FIG. 9, CAL FSM 1006 corresponds to receive link macro 928 of FIG. 9, and CAL FSM 1008 corresponds to transmit link macro 924 of FIG. 9. In addition, calibration system 1000 includes four CAL FSMs 1010, 1012, 1014, and 1016, which correspond to link macros within the same cluster (e.g., in this case cluster 930 of FIG. 9). CAL FSM 1010 corresponds to transmit link macro 932 of FIG. 9, CAL FSM 1012 corresponds to transmit link macro 934 of FIG. 9, CAL FSM 1014 corresponds to transmit link macro 936 of FIG. 9, and CAL FSM 1016 corresponds to transmit link macro 938 of FIG. 9.

With continued reference to FIG. 10, calibration system 1000 further incudes a node-level FSM (NODE FSM) 1030. NODE FSM 1030 corresponds to D2D node 910 of FIG. 9, making the top-level FSM for this node. FIG. 10 further shows cluster FSMs for other clusters that are not shown in FIG. 10. As an example, FIG. 10 shows CLUSTER FSMs 1026 and 1028, which correspond to other clusters associated with D2D node 910 itself or other D2D nodes within the same die. In terms of operation, each link macro level CAL FSM (e.g., CAL FSMs 1002, 1004, 1006, 1008, 1010, 1012, 1014, and 1016) measures aspects associated with the circuits being calibrated and communicates the calibration-related information associated with the current calibration stage to a corresponding cluster FSM (e.g., one of CLUSTER FSMs 1022 and 1024). In one example, the CLUSTER FSM waits for all the link macros within its cluster to complete the current stage of calibration. The CLUSTER FSMs communicate to the node FSM (e.g., NODE FSM 1030) the completion status when this occurs. Once all the clusters have communicated to the NODE FSM that they have finished the current stage of the calibration, the NODE FSM advances to the next stage of the calibration and communicates to the pertinent CLUSTER FSMs (e.g., in this case CLUSTER FSMs 1022 and 1024) to advance. The CLUSTER FSMs, in turn communicate to the CAL FSMs within the respective clusters to advance to the next stage of calibration. The clusters that are communicating in one direction are now able to receive the calibration stage information via other clusters that are communicating in the other direction. Although FIG. 10 shows calibration system 1000 as having a certain number of CAL FSMs and CLUSTER FSMs, that are hierarchically arranged in a certain manner, calibration system 1000 may include additional or fewer CAL FSMs and/or CLUSTER FSMs that are arranged differently.

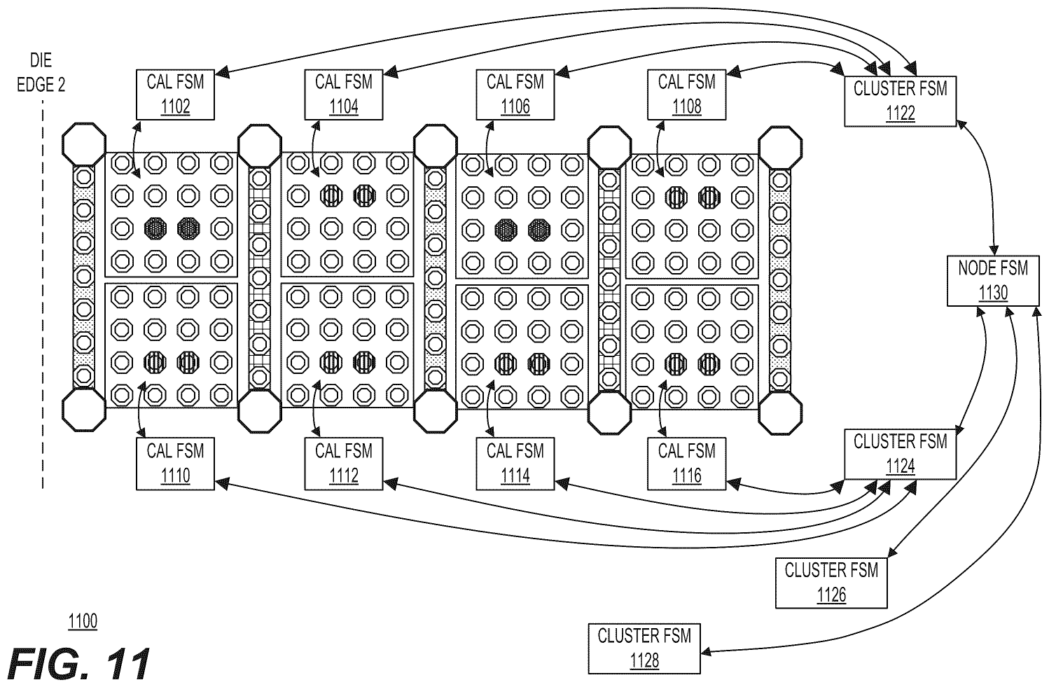

FIG. 11 shows a calibration system 1100 associated with D2D node 950 of FIG. 9. As noted earlier, D2D nodes 910 and 950 are located on separate dies and are interconnected via an asymmetric die-to-die interface. Calibration system 1000 described with respect to FIG. 10 corresponds to one die and calibration system 1100 corresponds to the other die. The two systems allow calibration of various aspects associated with the D2D links interconnecting two different die. Calibration system 1100 includes four more CAL FSMs 1102, 1104, 1106, and 1108, which correspond to link macros within the same cluster (e.g., in this case cluster 960 of FIG. 9). In this example, CAL FSM 1102 corresponds to transmit link macro 962 of FIG. 9, CAL FSM 1104 corresponds to receive link macro 966 of FIG. 9, CAL FSM 1106 corresponds to transmit link macro 964 of FIG. 9, and CAL FSM 1108 corresponds to receive link macro 968 of FIG. 9. In addition, calibration system 1100 includes four CAL FSMs 1110, 1112, 1114, and 1116, which correspond to link macros within the same cluster (e.g., in this case cluster 970 of FIG. 9). CAL FSM 1110 corresponds to receive link macro 972 of FIG. 9, CAL FSM 1112 corresponds to receive link macro 974 of FIG. 9, CAL FSM 1114 corresponds to receive link macro 976 of FIG. 9, and CAL FSM 1116 corresponds to receive link macro 978 of FIG. 9.

With continued reference to FIG. 11, calibration system 1100 further incudes a node-level FSM (NODE FSM) 1130. NODE FSM 1130 corresponds to D2D node 950 of FIG. 9, making the top-level FSM for this node. FIG. 11 further shows cluster FSMs for other clusters that are not shown in FIG. 11. As an example, FIG. 11 shows CLUSTER FSMs 1126 and 1128, which correspond to other clusters associated with D2D node 950 itself or other D2D nodes within the same die. In terms of operation, each link macro level CAL FSM (e.g., CAL FSMs 1102, 1104, 1106, 1108, 1110, 1112, 1114, and 1116) measures aspects associated with the circuits being calibrated and communicates the calibration-related information for the current calibration stage to a corresponding cluster FSM (e.g., one of CLUSTER FSMs 1122 and 1124). In one example, the CLUSTER FSM waits for all the link macros within its cluster to complete the current stage of calibration. The CLUSTER FSMs communicate to the node FSM (e.g., NODE FSM 1130) the completion status when this occurs. Once all the clusters have communicated to the NODE FSM that they have finished the current stage of the calibration, the NODE FSM advances to the next stage of the calibration and communicates to the pertinent CLUSTER FSMs (e.g., in this case CLUSTER FSMs 1122 and 1124) to advance. The CLUSTER FSMs, in turn communicate to the CAL FSMs within the respective clusters to advance to the next stage of calibration. The clusters that are communicating in one direction are now able to receive the calibration stage information via other clusters that are communicating in the other direction. Advantageously, the aggregation of calibration and initialization information using a hierarchy of FSMs effectively forms a back-channel at the node level even though no such back-channel exists at lower levels. Although FIG. 11 shows calibration system 1100 as having a certain number of CAL FSMs and CLUSTER FSMs that are hierarchically arranged in a certain manner, calibration system 1100 may include additional or fewer CAL FSMs and/or CLUSTER FSMs that are arranged differently.

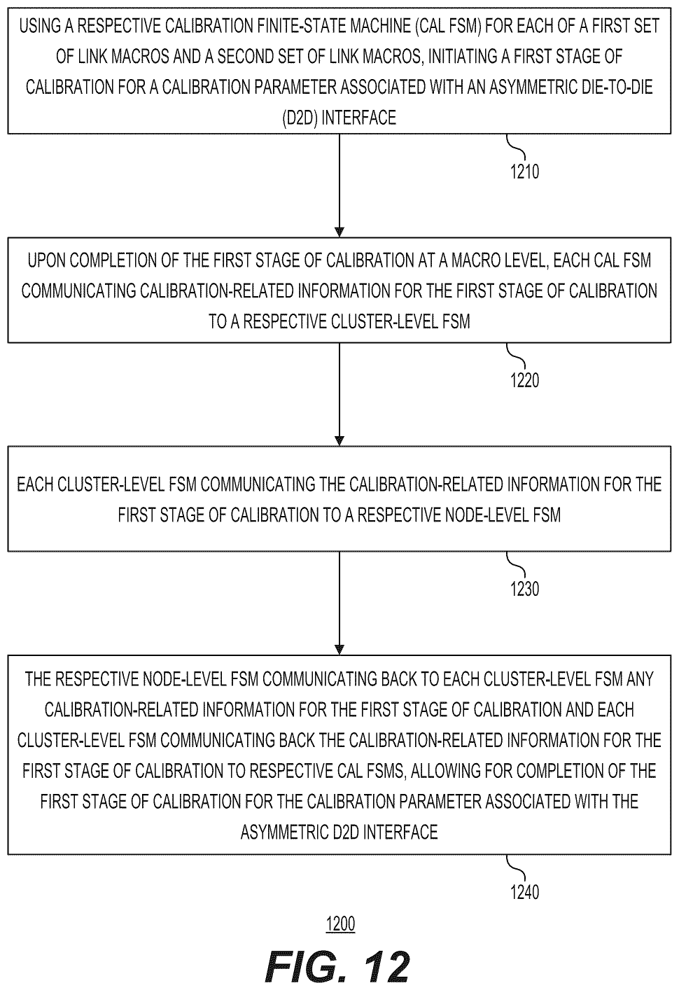

FIG. 12 shows a flow chart 1200 of a method for calibrating an asymmetric die-to-die (D2D) interface between a first die and second die, wherein the first die comprises a first die-to-die (D2D) node including a first set of clusters, wherein each of the first set of clusters comprises a first set of link macros, and wherein the second die comprises a second D2D node including a second set of clusters, wherein each of the second set of clusters comprises a second set of link macros. Step 1210 includes using a respective calibration finite-state machines (CAL FSM) for each of the first set of link macros and the second set of link macros, initiating a first stage of calibration for a calibration parameter associated with the asymmetric D2D interface. As an example, FIG. 10 shows, with respect to the first set of link macros, each link macro level CAL FSM (e.g., CAL FSMs 1002, 1004, 1006, 1008, 1010, 1012, 1014, and 1016) measures aspects associated with the circuits being calibrated and communicates the calibration-related information associated with the current calibration stage to a corresponding cluster FSM (e.g., one of CLUSTER FSMs 1022 and 1024). As an example, FIG. 11 shows, with respect to the second set of link macros, each link macro level CAL FSM (e.g., CAL FSMs 1102, 1104, 1106, 1108, 1110, 1112, 1114, and 1116) measures aspects associated with the circuits being calibrated and communicates the calibration-related information for the current calibration stage to a corresponding cluster FSM (e.g., one of CLUSTER FSMs 1122 and 1124).

Example calibrations parameters relate to the calibration of various components, included in the link macros and associated circuitry. As an example, link macros include voltage-controlled oscillators, whose frequency may need calibration. A CAL FSM can perform calibration of the frequency for the relevant voltage-controlled oscillators (VCOs) by using counters that can be used to compare the frequency output by a VCO with a reference frequency. Once the measurements have been made by the CAL FSM, those measurements can result in changes to current, capacitance, or voltage associated with the pertinent VCOs. Another calibration parameter relates to duty cycle correction. A CAL FSM can drive an auto-zero comparator to perform certain measurements associated with the duty cycle and can then determine changes to certain settings to correct any duty cycle issues. Yet another calibration parameter relates to driver termination.

Each of the link macros can be coupled to transmit or receive drivers, which include resistors and transistors requiring calibration. A CAL FSM can drive measurement circuitry to compensate for transistor threshold variations caused by manufacturing process variations. As an example, an analog impedance control loop can be used for compensating for the transistor threshold variations. Another CAL FSM can be used to calibrate an internal resistor using an off-chip precision resistor. Another CAL FSM can be used for coarse calibration of a resistor associated with the driver termination, as well. As an example, based on the calibration, the number of legs associated with the output impedance of a driver can be adjusted. Other CAL FSMs can be used to calibrate parameters associated with the receive side, as well. As an example, offset calibrations can be performed for matching resistors on the receive side.

With continued reference to FIG. 12, step 1220 includes upon completion of the first stage of the calibration at a macro level, each of the respective CAL FSMs communicating calibration-related information for the first stage of calibration to respective cluster-level FSMs. As an example, FIG. 10 shows, with respect to the first set of link macros, each link macro level CAL FSM (e.g., CAL FSMs 1002, 1004, 1006, 1008, 1010, 1012, 1014, and 1016) measures aspects associated with the circuits being calibrated and communicates the calibration-related information associated with the current calibration stage to a corresponding cluster FSM (e.g., one of CLUSTER FSMs 1022 and 1024). As an example, FIG. 11 shows, with respect to the second set of link macros, each link macro level CAL FSM (e.g., CAL FSMs 1102, 1104, 1106, 1108, 1110, 1112, 1114, and 1116) measures aspects associated with the circuits being calibrated and communicates the calibration-related information for the current calibration stage to a corresponding cluster FSM (e.g., one of CLUSTER FSMs 1122 and 1124). The measurements can include circuit-measurements related to any of the calibration parameters described earlier.

Step 1230 includes each cluster-level FSM communicating the calibration-related information for the first stage of calibration to a respective node-level FSM. In one example, the respective cluster-level FSM waits for all the link macros within its cluster to complete the current stage of calibration. As an example, with respect to FIG. 10, the CLUSTER FSM 1022 communicates to the node FSM (e.g., NODE FSM 1030) the completion status when this occurs. As another example, with respect to FIG. 11, the CLUSTER FSM 1122 communicates to the node FSM (e.g., NODE FSM 1130) the completion status when this occurs.

Step 1240 includes the respective node-level FSM communicating back to each cluster-level FSM any calibration-related information for the first stage of calibration and each cluster-level FSM communicating back the calibration-related information for the first stage of calibration to respective CAL FSMs, allowing for completion of the first stage of calibration for the calibration parameter associated with the asymmetric D2D interface. As an example, as part of this step, once all the clusters have communicated to the NODE FSM that they have finished the current stage of the calibration, the NODE FSM advances to the next stage of the calibration and communicates to the pertinent CLUSTER FSMs (e.g., in this case CLUSTER FSMs 1022, 1024, 1122, and 1124) to advance. The CLUSTER FSMs, in turn communicate to the CAL FSMs within the respective clusters to advance to the next stage of calibration. The clusters that are communicating in one direction are now able to receive the calibration stage information via other clusters that are communicating in the other direction. Advantageously, the aggregation of calibration and initialization information using a hierarchy of FSMs effectively forms a back-channel at the node level even though no such back-channel exists at lower levels.

In conclusion, the present disclosure relates to a method for calibrating an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The method includes using a respective calibration finite-state machine (CAL FSM) for each of the first set of link macros and the second set of link macros, initiating a first stage of calibration for a calibration parameter associated with the asymmetric D2D interface.

The method may further include upon completion of the first stage of the calibration at a macro level, each CAL FSM communicating calibration-related information for the first stage of calibration to a respective cluster-level FSM. The method may further include each cluster-level FSM communicating the calibration-related information for the first stage of calibration to a respective node-level FSM.

The method may further include the respective node-level FSM communicating back to each cluster-level FSM any calibration-related information for the first stage of calibration. The method may further include each cluster-level FSM communicating back the calibration-related information for the first stage of calibration to respective CAL FSMs, allowing for completion of the first stage of calibration for the calibration parameter associated with the asymmetric D2D interface.

The method may further include upon completion of the first stage of calibration, using the respective calibration finite-state machine (CAL FSM) for each of the first set of link macros and the second set of link macros, initiating a second stage of calibration for the calibration parameter associated with the asymmetric D2D interface. The method may further include upon completion of the second stage of the calibration at the macro level, each CAL FSM communicating calibration-related information for the second stage of calibration to the respective cluster-level FSM.

The method may further include each cluster-level FSM communicating the calibration-related information for the second stage of calibration to the respective node-level FSM. The method may further include the respective node-level FSM communicating back to each cluster-level FSM any calibration-related information for the second stage of calibration and each cluster-level FSM communicating back the calibration-related information for the second stage of calibration to the respective CAL FSMs, allowing for completion of the second stage of calibration for the calibration parameter associated with the asymmetric D2D interface.

The calibration parameter may correspond to one of a frequency calibration parameter, a duty cycle correction parameter, or a driver termination parameter. A CAL FSM associated with anyone of the first set of link macros can communicate finite state machine (FSM) state information, via a respective cluster-level FSM and a respective node-level FSM, to a second CAL FSM associated with anyone of the second set of link macros.

In another example, the present disclosure relates to a calibration system for an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The calibration system includes a respective calibration finite-state machine (CAL FSM) for each of the first set of link macros and the second set of link macros to initiate a first stage of calibration for a calibration parameter associated with the asymmetric D2D interface.

Upon completion of the first stage of the calibration at a macro level, each CAL FSM may be configured to communicate calibration-related information for the first stage of calibration to a respective cluster-level FSM. Each cluster-level FSM may be configured to communicate the calibration-related information for the first stage of calibration to a respective node-level FSM.

The respective node-level FSM may be configured to communicate back to each cluster-level FSM any calibration-related information for the first stage of calibration. Each cluster-level FSM may be configured to communicate back the calibration-related information for the first stage of calibration to respective CAL FSMs, allowing for completion of the first stage of calibration for the calibration parameter associated with the asymmetric D2D interface.

Upon completion of the first stage of calibration, using the respective calibration finite-state machine (CAL FSM) for each of the first set of link macros and the second set of link macros, the calibration system may further be configured to initiate a second stage of calibration for the calibration parameter associated with the asymmetric D2D interface. Moreover, upon completion of the second stage of the calibration at the macro level, each CAL FSM may be configured to communicate calibration-related information for the second stage of calibration to the respective cluster-level FSM. Each cluster-level FSM may be configured to communicate the calibration-related information for the second stage of calibration to the respective node-level FSM.

The respective node-level FSM may be configured to communicate back to each cluster-level FSM any calibration-related information for the second stage of calibration and each cluster-level FSM may be configured to communicate back the calibration-related information for the second stage of calibration to the respective CAL FSMs, allowing for completion of the second stage of calibration for the calibration parameter associated with the asymmetric D2D interface. The calibration parameter may correspond to one of a frequency calibration parameter, a duty cycle correction parameter, or a driver termination parameter. A CAL FSM associated with anyone of the first set of link macros can communicate finite state machine (FSM) state information, via a respective cluster-level FSM and a respective node-level FSM, to a second CAL FSM associated with anyone of the second set of link macros.

In yet another example, the present disclosure relates to a calibration system for an asymmetric die-to-die (D2D) interface between a first die and second die. The first die comprises a first die-to-die (D2D) node including a first set of clusters, where each of the first set of clusters comprises a first set of link macros. The second die comprises a second D2D node including a second set of clusters, where each of the second set of clusters comprises a second set of link macros. The calibration system includes a respective calibration finite-state machine (CAL FSM) for each of the first set of link macros and the second set of link macros to initiate a first stage of calibration for a calibration parameter associated with the asymmetric D2D interface.

Upon completion of the first stage of the calibration at a macro level, using a data lane associated with the asymmetric D2D interface, each CAL FSM may be configured to communicate calibration-related information for the first stage of calibration to a respective cluster-level FSM. Each cluster-level FSM may be configured to communicate the calibration-related information for the first stage of calibration, using the data lane associated with the asymmetric D2D interface, to a respective node-level FSM.

The respective node-level FSM may be configured to communicate back to each cluster-level FSM any calibration-related information for the first stage of calibration using the data lane associated with the asymmetric D2D interface. Each cluster-level FSM may be configured to communicate back the calibration-related information for the first stage of calibration to respective CAL FSMs, using the data lane associated with the asymmetric D2D interface, allowing for completion of the first stage of calibration for the calibration parameter associated with the asymmetric D2D interface.

Upon completion of the first stage of calibration, using the respective calibration finite-state machine (CAL FSM) for each of the first set of link macros and the second set of link macros, the calibration system may further be configured to initiate a second stage of calibration for the calibration parameter associated with the asymmetric D2D interface. Moreover, upon completion of the second stage of the calibration at the macro level, using the data lane associated with the asymmetric D2D interface, each CAL FSM may further be configured to communicate calibration-related information for the second stage of calibration to the respective cluster-level FSM using the data lane associated with the asymmetric D2D interface.

Each cluster-level FSM may further be configured to communicate the calibration-related information for the second stage of calibration to the respective node-level FSM using the data lane associated with the asymmetric D2D interface. Each cluster-level FSM may further be configured to communicate back the calibration-related information for the second stage of calibration to the respective CAL FSMs, using the data lane associated with the asymmetric D2D interface, allowing for completion of the second stage of calibration for the calibration parameter associated with the asymmetric D2D interface. The calibration parameter may correspond to one of a frequency calibration parameter, a duty cycle correction parameter, or a driver termination parameter.

It is to be understood that the methods, modules, and components depicted herein are merely exemplary. Alternatively, or in addition, the functionality described herein can be performed, at least in part, by one or more hardware logic components. For example, and without limitation, illustrative types of hardware logic components that can be used include Field-Programmable Gate Arrays (FPGAs), Application-Specific Integrated Circuits (ASICs), Application-Specific Standard Products (ASSPs), System-on-a-Chip systems (SOCs), or Complex Programmable Logic Devices (CPLDs). In an abstract, but still definite sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or inter-medial components. Likewise, any two components so associated can also be viewed as being “operably connected,” or “coupled,” to each other to achieve the desired functionality.

The functionality associated with some examples described in this disclosure can also include instructions stored in a non-transitory media. The term “non-transitory media” as used herein refers to any media storing data and/or instructions that cause a machine to operate in a specific manner. Exemplary non-transitory media include non-volatile media and/or volatile media. Non-volatile media include, for example, a hard disk, a solid state drive, a magnetic disk or tape, an optical disk or tape, a flash memory, an EPROM, NVRAM, PRAM, or other such media, or networked versions of such media. Volatile media include, for example, dynamic memory such as DRAM, SRAM, a cache, or other such media. Non-transitory media is distinct from, but can be used in conjunction with transmission media. Transmission media is used for transferring data and/or instruction to or from a machine. Exemplary transmission media, include coaxial cables, fiber-optic cables, copper wires, and wireless media, such as radio waves.

Furthermore, those skilled in the art will recognize that boundaries between the functionality of the above described operations are merely illustrative. The functionality of multiple operations may be combined into a single operation, and/or the functionality of a single operation may be distributed in additional operations. Moreover, alternative embodiments may include multiple instances of a particular operation, and the order of operations may be altered in various other embodiments.

Although the disclosure provides specific examples, various modifications and changes can be made without departing from the scope of the disclosure as set forth in the claims below. Accordingly, the specification and figures are to be regarded in an illustrative rather than a restrictive sense, and all such modifications are intended to be included within the scope of the present disclosure. Any benefits, advantages, or solutions to problems that are described herein with regard to a specific example are not intended to be construed as a critical, required, or essential feature or element of any or all the claims.

Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles.

Unless stated otherwise, terms such as “first” and “second” are used to arbitrarily distinguish between the elements such terms describe. Thus, these terms are not necessarily intended to indicate temporal or other prioritization of such elements.

What is claimed:

1. A method for calibrating an asymmetric die-to-die (D2D) interface between a first die and second die, wherein the first die comprises a first die-to-die (D2D) node including a first set of clusters, wherein each of the first set of clusters comprises a first set of link macros, wherein the second die comprises a second D2D node including a second set of clusters, and wherein each of the second set of clusters comprises a second set of link macros, the method comprising:
using a respective calibration finite-state machine (CAL FSM) for each of the first set of link macros and the second set of link macros, initiating a first stage of calibration for a calibration parameter associated with the asymmetric D2D interface;
upon completion of the first stage of the calibration at a macro level, each CAL FSM communicating calibration-related information for the first stage of calibration to a respective cluster-level FSM;
each cluster-level FSM communicating the calibration-related information for the first stage of calibration to a respective node-level FSM; and
the respective node-level FSM communicating back to each cluster-level FSM any calibration-related information for the first stage of calibration and each cluster-level FSM communicating back the calibration-related information for the first stage of calibration to respective CAL FSMs, allowing for completion of the first stage of calibration for the calibration parameter associated with the asymmetric D2D interface.

2. The method of claim 1, further comprising upon completion of the first stage of calibration, using the respective calibration finite-state machine (CAL FSM) for each of the first set of link macros and the second set of link macros, initiating a second stage of calibration for the calibration parameter associated with the asymmetric D2D interface.

3. The method of claim 2, further comprising upon completion of the second stage of the calibration at the macro level, each CAL FSM communicating calibration-related information for the second stage of calibration to the respective cluster-level FSM.

4. The method of claim 3, further comprising each cluster-level FSM communicating the calibration-related information for the second stage of calibration to the respective node-level FSM.

5. The method of claim 4, further comprising the respective node-level FSM communicating back to each cluster-level FSM any calibration-related information for the second stage of calibration and each cluster-level FSM communicating back the calibration-related information for the second stage of calibration to the respective CAL FSMs, allowing for completion of the second stage of calibration for the calibration parameter associated with the asymmetric D2D interface.

6. The method of claim 1, wherein the calibration parameter corresponds to one of a frequency calibration parameter, a duty cycle correction parameter, or a driver termination parameter.

7. The method of claim 1, wherein a CAL FSM associated with anyone of the first set of link macros can communicate finite state machine (FSM) state information, via a respective cluster-level FSM and a respective node-level FSM, to a second CAL FSM associated with anyone of the second set of link macros.

8. A calibration system for an asymmetric die-to-die (D2D) interface between a first die and second die, wherein the first die comprises a first die-to-die (D2D) node including a first set of clusters, wherein each of the first set of clusters comprises a first set of link macros, wherein the second die comprises a second D2D node including a second set of clusters, and wherein each of the second set of clusters comprises a second set of link macros, the calibration system comprising:
a respective calibration finite-state machine (CAL FSM) for each of the first set of link macros and the second set of link macros to initiate a first stage of calibration for a calibration parameter associated with the asymmetric D2D interface;
upon completion of the first stage of the calibration at a macro level, each CAL FSM to communicate calibration-related information for the first stage of calibration to a respective cluster-level FSM;
each cluster-level FSM to communicate the calibration-related information for the first stage of calibration to a respective node-level FSM; and
the respective node-level FSM to communicate back to each cluster-level FSM any calibration-related information for the first stage of calibration and each cluster-level FSM to communicate back the calibration-related information for the first stage of calibration to respective CAL FSMs, allowing for completion of the first stage of calibration for the calibration parameter associated with the asymmetric D2D interface.

9. The calibration system of claim 8, wherein upon completion of the first stage of calibration, using the respective calibration finite-state machine (CAL FSM) for each of the first set of link macros and the second set of link macros, the calibration system is further configured to initiate a second stage of calibration for the calibration parameter associated with the asymmetric D2D interface.

10. The calibration system of claim 9, wherein upon completion of the second stage of the calibration at the macro level, each CAL FSM is configured to communicate calibration-related information for the second stage of calibration to the respective cluster-level FSM.

11. The calibration system of claim 10, wherein each cluster-level FSM is configured to communicate the calibration-related information for the second stage of calibration to the respective node-level FSM.

12. The calibration system of claim 11, wherein the respective node-level FSM is configured to communicate back to each cluster-level FSM any calibration-related information for the second stage of calibration and each cluster-level FSM is configured to communicate back the calibration-related information for the second stage of calibration to the respective CAL FSMs, allowing for completion of the second stage of calibration for the calibration parameter associated with the asymmetric D2D interface.

13. The calibration system of claim 8, wherein the calibration parameter corresponds to one of a frequency calibration parameter, a duty cycle correction parameter, or a driver termination parameter.

14. The calibration system of claim 8, wherein a CAL FSM associated with anyone of the first set of link macros can communicate finite state machine (FSM) state information, via a respective cluster-level FSM and a respective node-level FSM, to a second CAL FSM associated with anyone of the second set of link macros.

15. A calibration system for an asymmetric die-to-die (D2D) interface between a first die and second die, wherein the first die comprises a first die-to-die (D2D) node including a first set of clusters, wherein each of the first set of clusters comprises a first set of link macros, wherein the second die comprises a second D2D node including a second set of clusters, wherein each of the second set of clusters comprises a second set of link macros, and wherein the calibration system comprising:
a respective calibration finite-state machine (CAL FSM) for each of the first set of link macros and the second set of link macros to initiate a first stage of calibration for a calibration parameter associated with the asymmetric D2D interface;
upon completion of the first stage of the calibration at a macro level, using a data lane associated with the asymmetric D2D interface, each CAL FSM to communicate calibration-related information for the first stage of calibration to a respective cluster-level FSM;
each cluster-level FSM to communicate the calibration-related information for the first stage of calibration, using the data lane associated with the asymmetric D2D interface, to a respective node-level FSM;
the respective node-level FSM to communicate back to each cluster-level FSM any calibration-related information for the first stage of calibration using the data lane associated with the asymmetric D2D interface; and
each cluster-level FSM to communicate back the calibration-related information for the first stage of calibration to respective CAL FSMs, using the data lane associated with the asymmetric D2D interface, allowing for completion of the first stage of calibration for the calibration parameter associated with the asymmetric D2D interface.

16. The calibration system of claim 15, wherein upon completion of the first stage of calibration, using the respective calibration finite-state machine (CAL FSM) for each of the first set of link macros and the second set of link macros, the calibration system is further configured to initiate a second stage of calibration for the calibration parameter associated with the asymmetric D2D interface.

17. The calibration system of claim 16, wherein upon completion of the second stage of the calibration at the macro level, using the data lane associated with the asymmetric D2D interface, each CAL FSM is further configured to communicate calibration-related information for the second stage of calibration to the respective cluster-level FSM using the data lane associated with the asymmetric D2D interface.

18. The calibration system of claim 17, wherein each cluster-level FSM is further configured to communicate the calibration-related information for the second stage of calibration to the respective node-level FSM using the data lane associated with the asymmetric D2D interface.

19. The calibration system of claim 18, wherein each cluster-level FSM is further configured to communicate back the calibration-related information for the second stage of calibration to the respective CAL FSMs, using the data lane associated with the asymmetric D2D interface, allowing for completion of the second stage of calibration for the calibration parameter associated with the asymmetric D2D interface.

20. The calibration system of claim 15, wherein the calibration parameter corresponds to one of a frequency calibration parameter, a duty cycle correction parameter, or a driver termination parameter.
